(19) United States
(12) Patent Application Publication
(10) Pub. No.: US 2015/0255426 A1
(43) Pub. Date: Sep. 10, 2015

(54) SEMICONDUCTOR DEVICE WITH REDUCED WARPAGE

(71) Applicant: Amkor Technology, Inc., Chandler, AZ (US)

(72) Inventors: Seung Nam Son, Seoul (KR); Pil Je Sung, Seoul (KR); Won Chul Do, Gyeonggi-do (KR); JungBae Lee, Seoul (KR); Ji Hun Lee, Seoul (KR)

(21) Appl. No.: 14/546,484

(22) Filed: Nov. 18, 2014

(30) Foreign Application Priority Data
Mar. 4, 2014 (KR) 10-2014-0025630

(51) Int. Cl. H01L 23/00; H01L 25/065; H01L 23/48; H01L 21/78; H01L 21/56; H01L 21/768; H01L 25/00; H01L 23/31

(52) U.S. Cl. CPC H01L 24/96; H01L 25/50; H01L 25/0655; H01L 23/3178; H01L 21/78; H01L 21/561; H01L 21/563; H01L 24/81; H01L 24/17; H01L 21/76898; H01L 23/481; H01L 23/562; H01L 2224/16227; H01L 2224/81801

(57) ABSTRACT

A semiconductor device with reduced warpage is disclosed and may, for example, include bonding at least two semiconductor die to a substrate, forming underfill material between the at least two semiconductor die and the substrate and between the at least two semiconductor die, and removing a portion of the underfill material between the at least two semiconductor die, thereby forming a groove. The at least two semiconductor die and the underfill material may, for example, be encapsulating utilizing an encapsulant. The groove may, for example, be filled using the encapsulant. The underfill material between the at least two semiconductor die may, for example, be removed utilizing laser etching. The underfill material between the at least two semiconductor die may, for example, be removed to a depth of 60-70% of a thickness of the at least two semiconductor die.

### CROSS-REFERENCE TO RELATED APPLICATIONS

The present application makes reference to, claims priority to, and claims the benefit of Korean Patent Application No. 10-2014-0025630, filed on Mar. 4, 2014, the contents of which are hereby incorporated herein by reference, in their entirety.

### FIELD

Certain embodiments of the disclosure relate to semiconductor chip packaging. More specifically, certain embodiments of the disclosure relate to a semiconductor device with reduced warpage.

### BACKGROUND

In general, a semiconductor package includes a semiconductor die, a plurality of leads electrically connected to the semiconductor die and an encapsulant encapsulating the semiconductor die and the leads.

Along with the tendency toward miniaturization of electronic products, the electronic products need to have high performance. Accordingly, research and development of various techniques for providing high-capacity semiconductor packages are under way. One of the techniques for providing high-capacity semiconductor packages is to increase the capacity of a memory chip, that is, to achieve high integration of memory chips. The high integration of memory chips may be achieved by integrating as many cells as possible in a semiconductor die space.

However, warpage may occur to a semiconductor package due to a difference between coefficients of thermal expansion between silicon forming a semiconductor die and an underfill material underfilling the semiconductor die. The warpage may lower reliability of the semiconductor package and may cause severe defects to the operation of a semiconductor device.

Further limitations and disadvantages of conventional and traditional approaches will become apparent to one of skill in the art, through comparison of such systems with the present disclosure as set forth in the remainder of the present application with reference to the drawings.

### BRIEF SUMMARY

A semiconductor device with reduced warpage, substantially as shown in and/or described in connection with at least one of the figures, as set forth more completely in the claims.

Various advantages, aspects and novel features of the present disclosure, as well as details of an illustrated embodiment thereof, will be more fully understood from the following description and drawings.

### BRIEF DESCRIPTION OF SEVERAL VIEWS OF THE DRAWINGS

FIGS. 1 to 5A and 6 to 11 are partially cross-sectional views sequentially illustrating a method for fabricating a semiconductor package according to an embodiment of the present disclosure.

FIG. 5B is a partially enlarged view illustrating a region between semiconductor dies in a semiconductor package according to an embodiment of the present disclosure.

FIG. 5C is a graph illustrating warpage analysis results of a semiconductor package shown in FIG. 4 and a semiconductor package shown in FIG. 5A.

### DETAILED DESCRIPTION

Certain aspects of the disclosure may be found in method for manufacturing a semiconductor device comprising bonding at least two semiconductor die to a substrate, forming underfill material between the at least two semiconductor die and the substrate and between the at least two semiconductor die, and removing a portion of the underfill material between the at least two semiconductor die, thereby forming a groove. The at least two semiconductor die and the underfill material may be encapsulated utilizing an encapsulant. The groove may be filled using the encapsulant. The underfill material between the at least two semiconductor die may be removed utilizing laser etching. The portion of the underfill material between the at least two semiconductor die may be removed to a depth of 60-70% of a thickness of the at least two semiconductor die. The substrate may be grinded to expose a through electrode. A solder ball may be formed on the exposed through electrode. The substrate may be diced into individual semiconductor packages. One of the individual semiconductor packages may be bonded to a circuit board using the solder ball. A top surface of the encapsulant and a top surface of the at least two semiconductor die may be coplanar.

Various aspects of the present disclosure may be embodied in many different forms and should not be construed as being limited to the example embodiments set forth herein. Rather, these example embodiments of the disclosure are provided so that this disclosure will be thorough and complete and will convey various aspects of the disclosure to those skilled in the art.

In the drawings, the thickness of layers and regions are exaggerated for clarity. Here, like reference numerals refer to like elements throughout. As used herein, the term “and/or” includes any and all combinations of one or more of the associated listed items. In addition, the terminology used herein is for the purpose of describing particular embodiments only and is not intended to be limiting of the disclosure. As used herein, the singular forms are intended to include the plural forms as well, unless the context clearly indicates otherwise. It will be further understood that the terms “comprises,” “comprising,” “includes,” and/or “including,” when used in this specification, specify the presence of stated features, numbers, steps, operations, elements, and/or components, but do not preclude the presence or addition of one or more other features, numbers, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

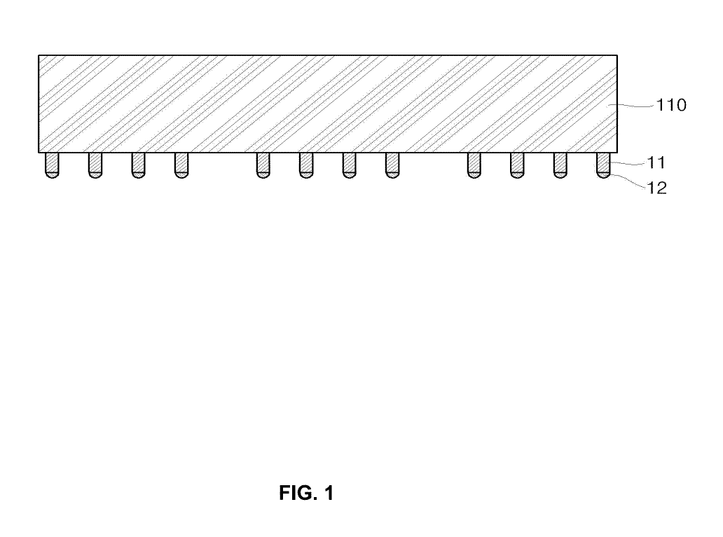

First, as illustrated in FIG. 1, a plurality of bumps 11 and 12 are formed on a bottom surface of the wafer 110. The bumps 11 and 12 may, for example, be formed by a copper pillar 11 and a solder cap 12 formed at an end of the copper pillar 11.

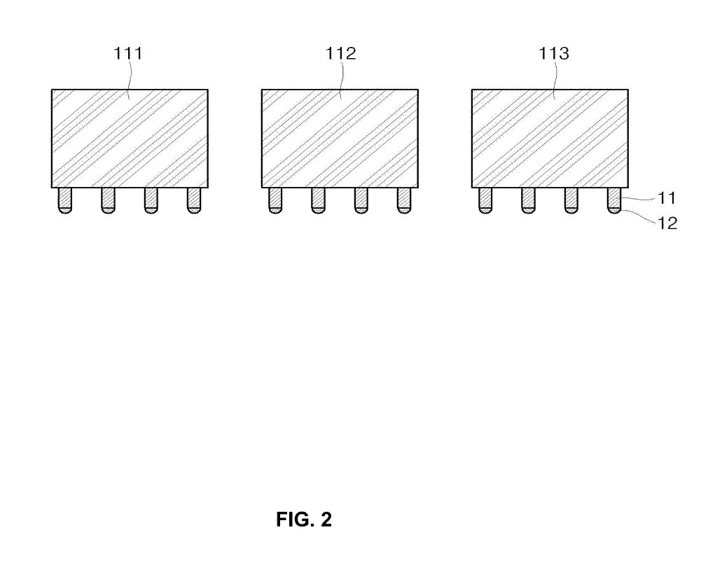

Thereafter, as illustrated in FIG. 2, the wafer 110 may be separated into a plurality of semiconductor dies 111, 112 and 113 by a sawing process. The sawing process may, for example, be performed by sawing equipment (e.g., a blade or a laser drill).

The plurality of semiconductor dies 111, 112 and 113 may include a general memory, a graphics processing unit (GPU), a central processing unit (CPU) and equivalents thereof, but aspects of the present disclosure are not limited thereto.

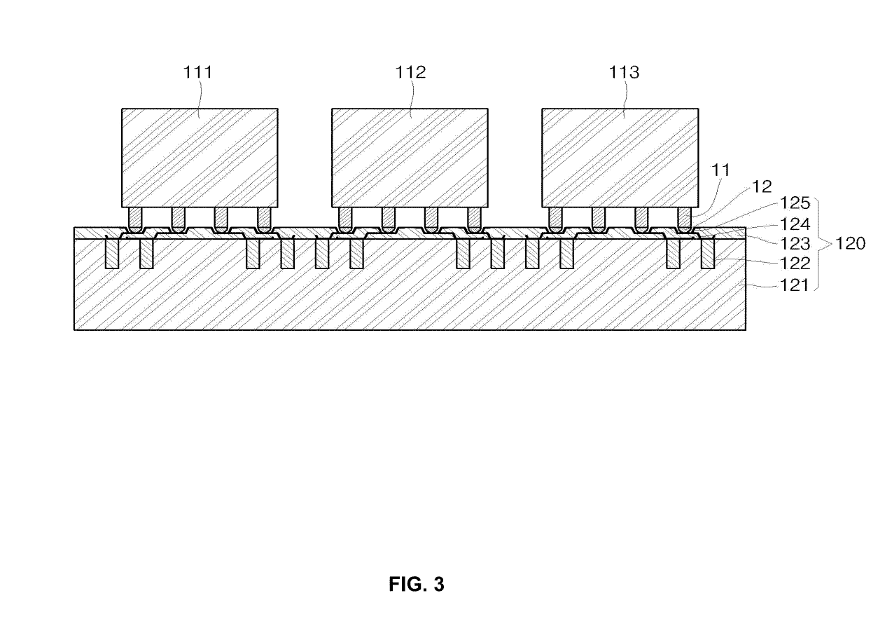

Referring to FIG. 3, the semiconductor dies 111, 112 and 113 are mounted on the interposer 120. Though the interposer 120 is utilized as an example illustration, the interposer 120 may for example be replaced by a non-interposer substrate.

The interposer 120 may, for example, comprise a substrate 121, a through electrode 122, a dielectric layer 123, a re-distribution layer (RDL) 124 and an under bump metallurgy (UBM) 125.

The substrate 121 may be at least one or more selected from a silicon block having planar top and bottom surfaces, glass and equivalents thereof, but aspects of the present disclosure are not limited thereto.

The through electrode 122 may, for example, be formed by filling a conductive material in a through hole to be formed to a predetermined depth from the top surface of the substrate 121. For example, the through hole of the through electrode 122 may be formed by laser drilling or chemical etching, but aspects of the present disclosure are not limited thereto.

The through electrode 122 may, for example, be formed by filling a conductive material selected from the group comprising copper (Cu), gold (Au), silver (Ag), aluminum (Al) or equivalents thereof, but aspects of the present disclosure are not limited thereto.

In addition, the through electrode 122 may be formed by one or more selected from physical vapor deposition (PVD), chemical vapor deposition (CVD), electroplating or electroless plating, and equivalents thereof, but aspects of the present disclosure are not limited thereto.

Although not shown, an insulation layer may fill an inner wall of the through electrode 122.

The dielectric layer 123 may comprise polyimide (PI), benzo cyclobutene (BCB), poly benz oxazole (PBO) or an equivalent thereof, to protect the re-distribution layer 124 from an external environment, but aspects of the present disclosure are not limited thereto.

The re-distribution layer 124 may, for example, be electrically connected to one side of the through electrode 122 and may comprise copper (Cu), gold (Au), silver (Ag), nickel (Ni) or an equivalent thereof. The UBM 125 may, for example, be electrically connected to one side of the RDL 124 to be exposed to the outside of the dielectric layer 123 and may comprise copper (Cu), gold (Au), silver (Ag), nickel (Ni) or an equivalent thereof, but aspects of the present disclosure are not limited thereto.

For example, the bumps 11 and 12 of the semiconductor dies 111, 112 and 113 may be mechanically and electrically connected to the UBM 125. The bumps 11 and 12 may, for example, include general solder bumps, and a solder (not shown) may be pre-formed on top surfaces of the bumps 11 and 12 and the UBM 125 to facilitate connections of the bumps 11 and 12. In such a manner, the semiconductor dies 111, 112 and 113 may be electrically connected to the RDL 124 and the through electrode 122 provided on the interposer 120.

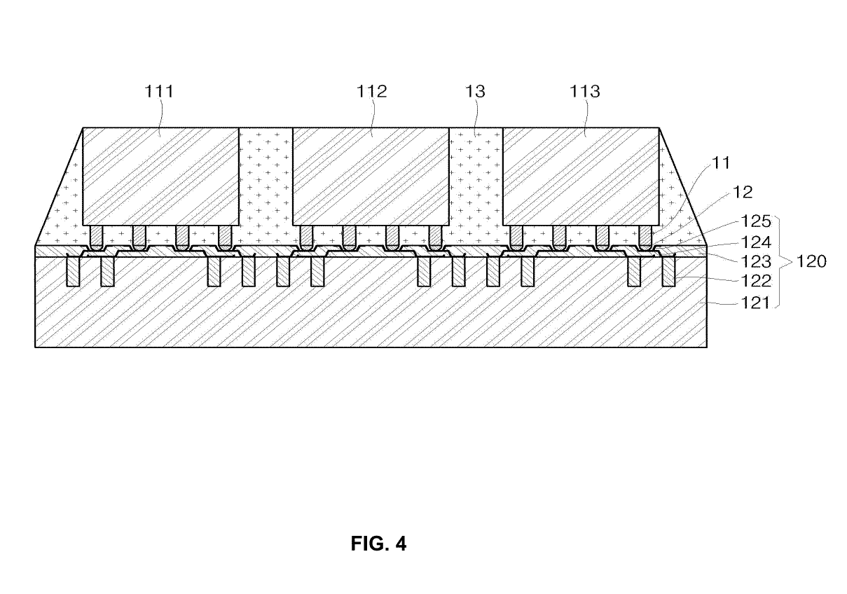

Referring to FIG. 4, the underfill 13 may, for example, be filled between the semiconductor dies 111, 112 and 113 and the interposer 120.

The underfill 13 may, for example, connect a bump connecting portion between the semiconductor dies 111, 112 and 113 and the interposer 120 from external factors generated during a semiconductor package fabricating process, such as mechanical shock or corrosion. The underfill 13 may, for example, comprise one or more selected from the group comprising epoxy, a thermoplastic material, a thermocurable material, polyimide, polyurethane, a polymeric material, filled epoxy, a filled thermoplastic material, a filled thermocurable material, filled polyimide, filled polyurethane, a filled polymeric material, fluxing underfill, and equivalents thereof, but aspects of the present disclosure are not limited thereto.

The underfill 13 may, for example, fill spaces between the semiconductor dies 111, 112 and 113 and the interposer 120 through, for example capillary action, and fill the spaces between the semiconductor dies 111, 112 and 113. Though shown as completely filling the spaces between the semiconductor dies 111, 112 and 113 to the top level of the semiconductor dies 111, 112 and 113, such complete filling of the spaces is not required. Additionally, though the underfill is illustrated as ramping up from the interposer 120 to the top surface of the outer semiconductor dies 11 and 113, the extent of such ramping and the specific shape of such ramping is not required.

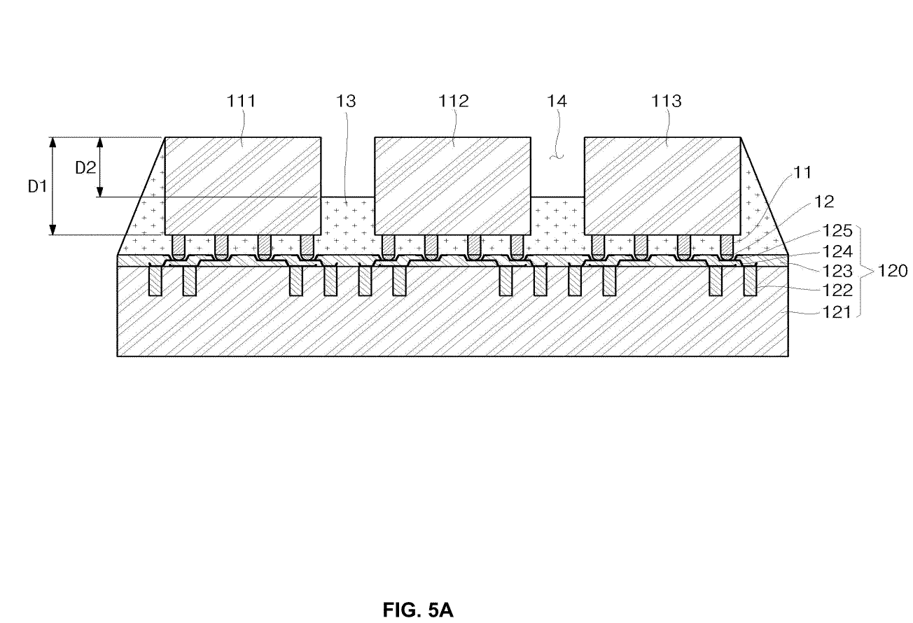

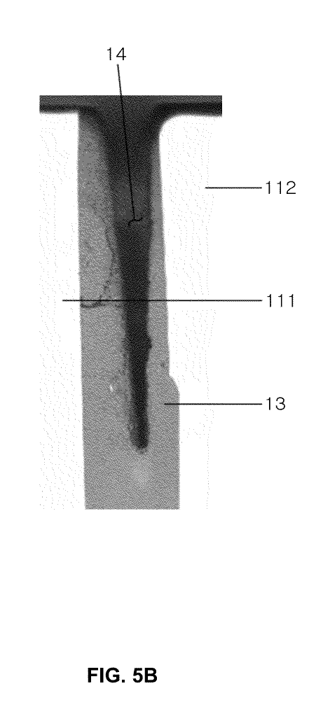

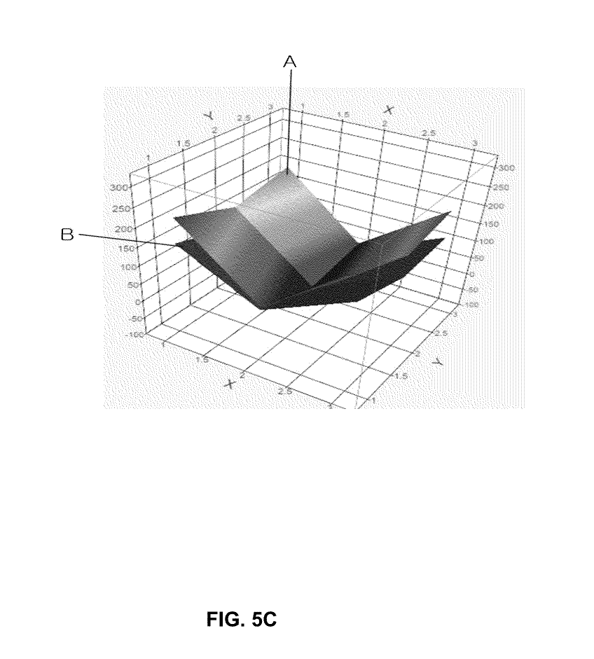

Referring to FIG. 5A, a portion of the underfill 13 between the semiconductor dies 111, 112 and 113 may be removed, thereby forming a groove 14.

The groove 14 may, for example, be formed by a laser etching process using laser beams or laser drilling, or a drilling process. However, when the groove 14 is formed by a mechanical process, particles may be formed between each of the semiconductor dies 111, 112 and 113, and the remaining underfill 13 may be highly prone to cracks.

For brevity, the groove 14 is cleanly illustrated in FIG. 5A, but the present disclosure does not limit the shape of the groove 14 to that illustrated in FIG. 5A. For example, the groove 14 may comprise sloped sides, for example with the sloped sides formed by underfill material still adhered to side surfaces of the semiconductor dies 111, 112 and 113. Also for example, the groove 14 may comprise straight sides, for example with straight sides formed by underfill material still adhered to side surfaces of the semiconductor dies 111, 112 and 113. Additionally for example, the groove 114 may comprise stepped sides, for example with at least a portion of the steps sides formed by underfill material still adhered to side surfaces of the semiconductor dies 111, 112 and 113. Further for example, in a scenario in which sides of the groove are defined by underfill material that is still adhered to side surfaces of semiconductor dies 111, 112 and 113 (e.g., underfill material that was not removed when forming the groove), the sides of the groove may comprise different respective thicknesses of underfill material, the sides of the groove may be asymmetrical, etc.

FIG. 5B is a partially enlarged view illustrating a region between semiconductor dies in a semiconductor package according to an embodiment of the present disclosure.

When the groove 14 is formed by laser etching, as shown in FIG. 5B, the groove 14 may, for example, be shaped like an inverted triangle such that its width decreases as its depth increases.

As the depth of the groove 14 increases, twisting or warpage may be effectively prevented from occurring during a semiconductor manufacturing process. However, as the depth of the groove 14 increases, the semiconductor dies 111 and 112 may be damaged and/or at least more susceptible to damage. Thus, for example, a depth D2 of the groove 14 of approximately 60% to 70% of a height D1 of each of the semiconductor dies 111 and 112 may be utilized. In other words, a height of the remaining underfill 13 may, for example, be approximately 30% to 40% of the height D1 of each of the semiconductor dies 111 and 112. Also for example, the depth D2 may be 50% to 70% of the height D1, the depth D2 may be 60% to 80% of the height D1, etc.

FIG. 5C is a graph illustrating warpage analysis results of a semiconductor package shown in FIG. 4 and a semiconductor package shown in FIG. 5A.

The graph A of FIG. 5C illustrates a warpage analysis result of the semiconductor package shown in FIG. 4, and the graph B of FIG. 5C illustrates a warpage analysis result of the semiconductor package shown in FIG. 5A. In detail, the graph A illustrates warpage occurring to the semiconductor package from which the underfill 13 between the semiconductor dies 111, 112 and 113 is not removed, and the graph B illustrates warpage occurring to the semiconductor package from which a portion of the underfill 13 between the semiconductor dies 111, 112 and 113 is removed.

For example, as illustrated in FIG. 5C, it can be confirmed that the semiconductor package from which the portion of the underfill 13 between the semiconductor dies 111, 112 and 113 is removed undergoes less warpage than the semiconductor package from which the underfill 13 is not removed

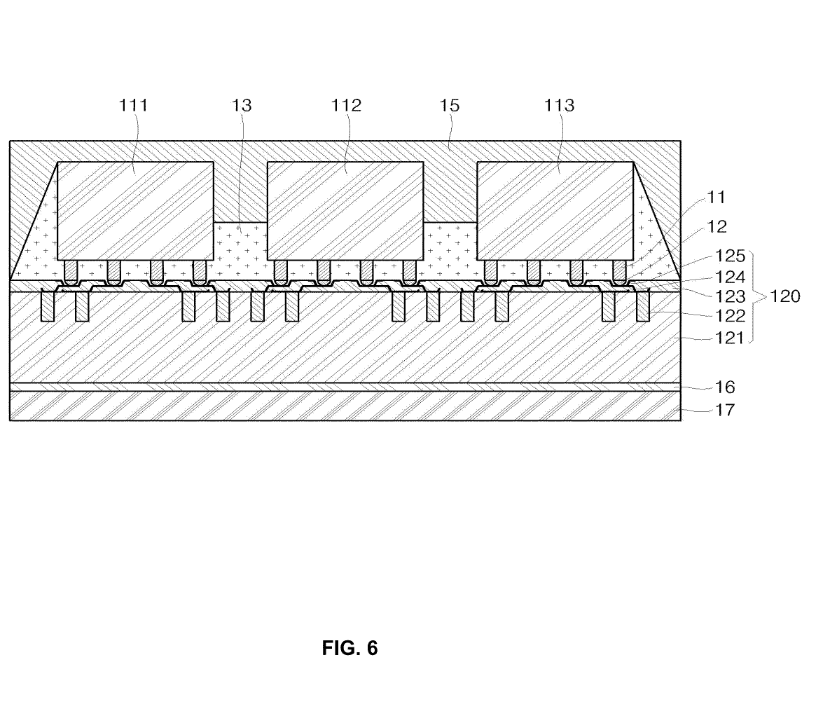

Referring to FIG. 6, the semiconductor dies 111, 112 and 113 and the interposer 120 are encapsulated using the encapsulant 15. In addition, a wafer support system (WSS) 17 is attached to a bottom surface of the interposer 120 using an adhesion member 16.

The encapsulant 15 may, for example, protect the semiconductor dies 111, 112 and 113 and the interposer 120 from external shock or oxidation by completely encapsulating the same. The encapsulant 15 may, for example, be an epoxy compound capable of encapsulating using a mold, a liquid encapsulating member capable of encapsulating using a dispenser, and equivalents thereof, but aspects of the present disclosure are not limited thereto.

The adhesion member 16 may, for example, employ one or more selected from the group comprising a general liquid epoxy adhesive, an adhesive film, an adhesive tape, and equivalents thereof, but aspects of the present disclosure are not limited thereto.

In addition, the WSS 17 may be made of glass or a silicon block, but aspects of the present disclosure are not limited thereto.

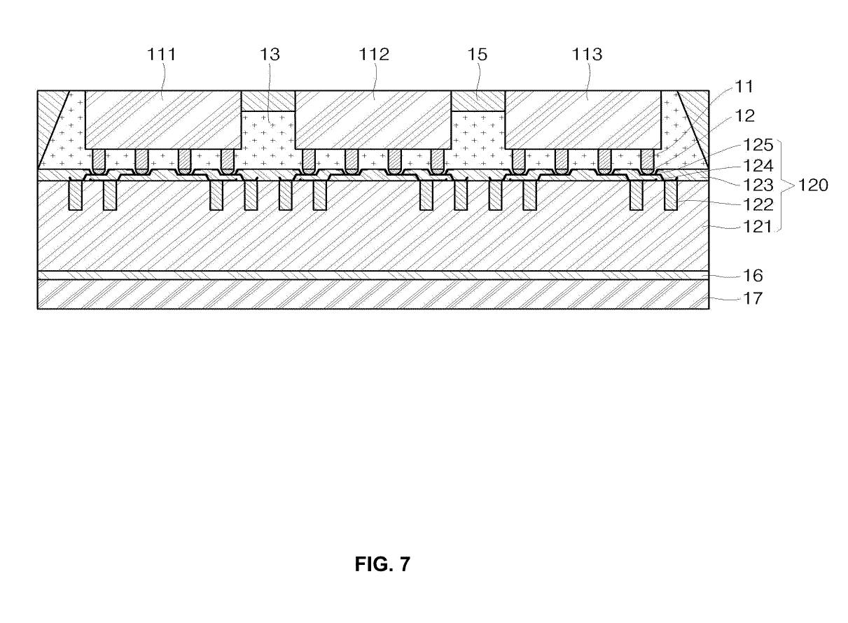

Referring to FIG. 7, unnecessary portions of the semiconductor dies 111, 112 and 113 may, for example, be removed by first grinding top surfaces of the semiconductor dies 111, 112 and 113. The first grinding may, for example, be performed using, for example, a diamond grinder or an equivalent thereof, but aspects of the present disclosure are not limited thereto.

An active layer (not shown) of each of the semiconductor dies 111, 112 and 113 is not exposed to the outside by the first grinding, instead the first grinding is performed on an inactive side of the semiconductor dies 111, 112 and 113. The underfill 13 between the semiconductor dies 111, 112 and 113 (or, for example, at least the parts of such semiconductor dies 111, 112 and 113 remaining after the first grinding) is not exposed by the first grinding. For example, only portions of the encapsulant 15 above the top surface of each of the semiconductor dies 111, 112 and 113 are removed by the first grinding.

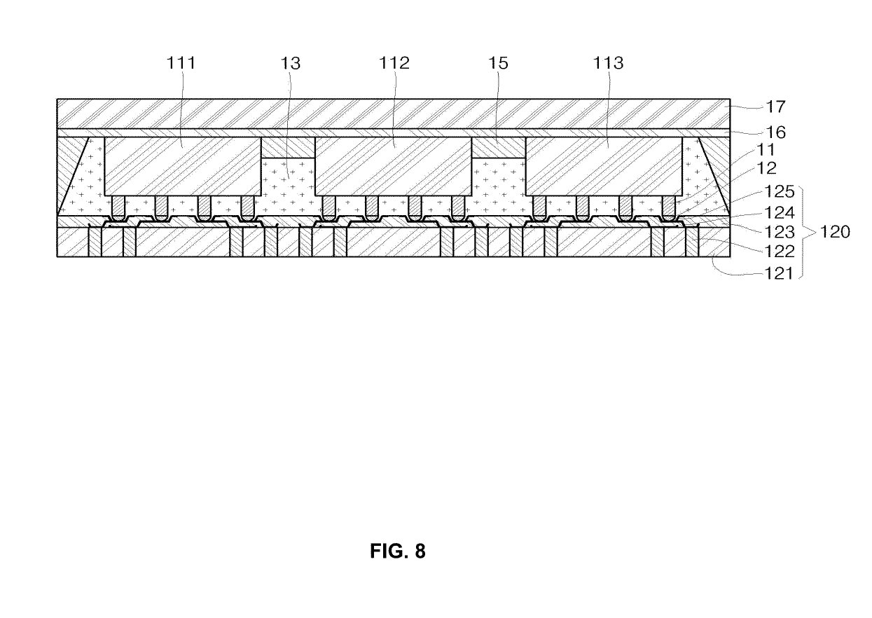

Referring to FIG. 8, unnecessary portions of the substrate 121 may, for example, be removed to expose the through electrode 122 by grinding the bottom surface of the interposer 120 to a predetermined thickness. The second grinding may be performed using, for example, a diamond grinder or an equivalent thereof, but aspects of the present disclosure are not limited thereto. The WSS 17 may then, for example, be separated from the bottom surface of the interposer 120 and attached to top surfaces of the semiconductor dies 111, 112 and 113 and/or the encapsulant 15 using the adhesion member 16. Note that the same WSS 17 as illustrated in FIG. 7 may be used in FIG. 8, but the respective WSS 17 items may also be different.

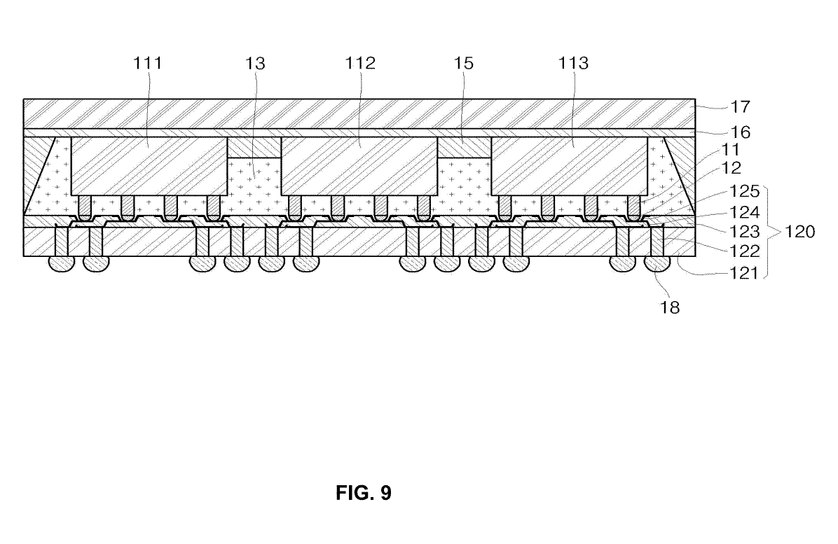

Next, referring to FIG. 9, each of the first solder balls 18 may, for example, be attached to the through electrode 122 exposed by the second grinding. The first solder balls 18 may be made of a metallic material such as lead/tin (Pb/Sn) or leadless Sn, and equivalents thereof, but aspects of the present disclosure are not limited thereto. Note that such solder ball attachment may be a direct or indirect attachment. For example, intervening pads may be formed on the exposed ends of the through electrodes 122 to which the solder balls 18 may be directly attached.

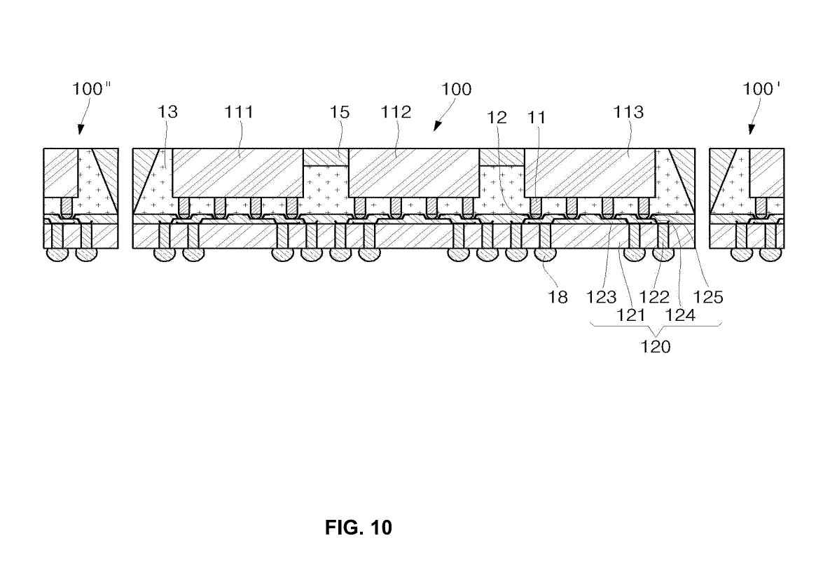

Referring to FIG. 10, a sawing process may, for example, be performed on the semiconductor package having the first solder balls 18 attached thereto to separate the semiconductor package into a first semiconductor package 100, a second semiconductor package 100′ and a third semiconductor package 100″. The sawing process may, for example, be performed using sawing equipment (for example, a blade or a laser drill). The adhesion member 16 and the WSS 17 may, for example, be removed before, during, or after the sawing process.

In such a manner, the example semiconductor package 100 according to the present disclosure is completed in the form of a flip chip type of package. Therefore, the flip-chip type semiconductor package 100 may, for example, be mounted on a circuit board for a general semiconductor device or semiconductor package. The semiconductor package according to the present disclosure may, for example, also be mounted on a mother board or main board.

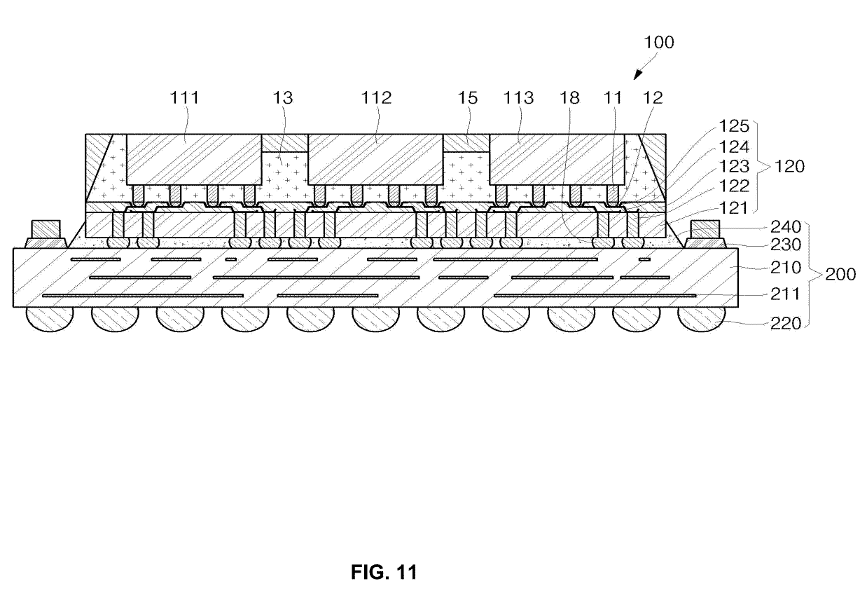

Referring to FIG. 11, the discrete first semiconductor package 100 may, for example, be mounted on a circuit board 200 through the first solder balls 18. In addition, an underfill 240 may, for example, be filled between the bottom surface of the interposer 120 and the top surface of the circuit board 200, followed by curing, thereby forming the semiconductor package. The circuit board 200 may, for example, comprise a packaging substrate, a circuit board substrate to which integrated circuit packages are attached, etc.

Since the underfill 240 may, for example, comprise the same material as the underfill 13, a detailed description thereof will be omitted.

The circuit board 200 includes an insulation body 210 including circuit patterns 211 electrically connected to each other, second solder balls 220 electrically connected to the circuit patterns 211, and a passive element 230 mounted on a top surface of the insulation body 210. The second solder balls 220 may, for example, be electrically connected to an external device (not shown) and may, for example, be formed using substantially the same material and substantially the same method with first solder balls 18. The second solder balls 220 may, for example, be formed to have a larger diameter than the first solder balls 18, but aspects of the present disclosure are not limited thereto.

Further, as described above, the first solder balls 18 of the flip-chip type first semiconductor package 100 may, for example, be electrically connected to the circuit patterns 211 of the circuit board 200.

This disclosure provides example embodiments supporting the present disclosure. The scope of the present disclosure is not limited by these example embodiments. Numerous variations, whether explicitly provided for by the specification or implied by the specification, such as variations in structure, dimension, type of material and manufacturing process, may be implemented by one skilled in the art in view of this disclosure.

In an example embodiment of the disclosure, a method for manufacturing a semiconductor device may comprise bonding a at least two semiconductor die to a substrate, forming underfill material between the at least two semiconductor die and the substrate and between the at least two semiconductor die, and removing a portion of the underfill material between the at least two semiconductor die, thereby forming a groove. The at least two semiconductor die and the underfill material may be encapsulating utilizing an encapsulant. The groove may be filled using the encapsulant. The underfill material between the at least two semiconductor die may be removed utilizing laser etching. The portion of the underfill material between the at least two semiconductor die may be removed to a depth of 60-70% of a thickness of the at least two semiconductor die. The substrate may be grinded to expose a through electrode. A solder ball may be formed on the exposed through electrode. The substrate may be diced into individual semiconductor packages. One of the individual semiconductor packages may be bonded to a circuit board using the solder ball. A top surface of the encapsulant and a top surface of the at least two semiconductor die may be coplanar.

In one aspect, the present disclosure provides a method for fabricating a semiconductor package, the method including (A) preparing at least two semiconductor dies, (B) preparing an interposer, (C) bonding the at least two semiconductor dies on the interposer, (D) filling an underfill between the interposer and the at least two semiconductor dies, and (E) removing at least a portion of the underfill between the at least two semiconductor dies.

Step (A) may, for example, include (A-1) forming a plurality of bumps on a bottom surface of a wafer, and (A-2) sawing the wafer to separate the same into at least two semiconductor dies. Step (B) may, for example, include (B-1) forming a through electrode to a predetermined depth from a top surface of a substrate. In addition, step (B) may, for example, include (B-2) forming a dielectric layer on the top surface of the substrate, and (B-3) forming a re-distribution layer in the dielectric layer to be electrically connected to the through electrode.

Step (B) may, for example, further include (B-4) forming an under bump metallurgy to be electrically connected to the re-distribution layer and to be exposed to a top portion of the dielectric layer. The substrate may, for example, comprise silicon or glass. In step (C), the bump may, for example, be bonded on the under bump metallurgy. In step (E), the underfill between the at least two semiconductor dies may, for example, be removed by laser etching. In step (E), the underfill between the at least two semiconductor dies may, for example, be removed by 60% to 70% of a thickness of each of the at least two semiconductor dies.

The method may, for example, further include (F) encapsulating the at least two semiconductor dies and the interposer using an encapsulant. The method may, for example, further include (G-1) first grinding the encapsulant, the underfill and top surfaces of the at least two semiconductor dies, and (G-2) second grinding a bottom surface of the substrate to expose the through electrode. The method may, for example, further include (H) attaching first solder balls to the exposed through electrode. The method may, for example, further include (I) mounting the attached first solder balls to a top surface of a circuit board.

The method may, for example, further include (J) attaching second solder balls to a bottom surface of the circuit board. In another aspect, the present disclosure provides a semiconductor package including an interposer including a through electrode formed on a substrate, a re-distribution layer formed on the substrate to be electrically connected to the through electrode and a dielectric layer protecting the re-distribution layer, at least two semiconductor dies mounted on the interposer to be electrically connected to the re-distribution layer, and an underfill filled between the interposer and the at least two semiconductor dies, wherein at least a portion of the underfill between the at least two semiconductor dies may be removed. The interposer may further include an under bump metallurgy electrically connected to the re-distribution layer and exposed to a top portion of the dielectric layer.

Each of the at least two semiconductor dies may, for example, include a plurality of bumps formed on its bottom surface and the plurality of bumps bonded to the under bump metallurgy. The underfill between the at least two semiconductor dies may, for example, be removed by laser etching. The underfill between the at least two semiconductor dies may, for example, remain by 30% to 40% of a thickness of each of the at least two semiconductor dies. The semiconductor package may, for example, further include an encapsulant encapsulating the at least two semiconductor dies.

A region with the underfill removed therefrom may, for example, be filled with the encapsulant. The substrate may, for example, include silicon or glass. The through electrode exposed to the bottom surface of the interposer may, for example, be electrically connected to a circuit board through first solder balls.

While various aspects of the present disclosure have been described with reference to certain supporting embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for manufacturing a semiconductor device, the method comprising:
bonding at least two semiconductor die to a substrate;
forming underfill material between the at least two semiconductor die and the substrate and between the at least two semiconductor die; and
removing a portion of the underfill material between the at least two semiconductor die thereby forming a groove.

2. The method according to claim 1, comprising encapsulating the at least two semiconductor die and the underfill material utilizing an encapsulant.

3. The method according to claim 2, comprising filling the groove using the encapsulant.

4. The method according to claim 1, wherein said removing a portion of the underfill material comprises removing the portion of the underfill material between the at least two semiconductor die utilizing laser etching.

5. The method according to claim 1, wherein said removing a portion of the underfill material comprises removing the portion of the underfill material between the at least two semiconductor die to a depth of 60-70% of a thickness of the at least two semiconductor die.

6. The method according to claim 1, comprising grinding the substrate to expose a through electrode.

7. The method according to claim 6, comprising forming a solder ball on the exposed through electrode.

8. The method according to claim 7, comprising dicing the substrate into individual semiconductor packages.

9. The method according to claim 8, comprising bonding one of the individual semiconductor packages to a circuit board using the solder ball.

10. The method according to claim 2, comprising grinding a top surface of the encapsulant and a top surface of the at least two semiconductor die to establish coplanarity between respective top surfaces of the at least two semiconductor die and a top surface of the encapsulant.

11. A semiconductor device, the device comprising:
a substrate;
at least two semiconductor die bonded to a first surface of the substrate;
underfill material between the at least two semiconductor die and the substrate and between the at least two semiconductor die; and
a groove in the underfill material between the at least two semiconductor die.

12. The device according to claim 11, wherein the at least two semiconductor die and the underfill material are encapsulated in an encapsulant.

13. The device according to claim 12, wherein the groove is filled with the encapsulant.

14. The device according to claim 11, wherein the groove is v-shaped.

15. The device according to claim 11, wherein a depth of the groove is 60-70% of a thickness of the at least two semiconductor die.

16. The device according to claim 11, wherein a through electrode is exposed at a second surface opposite to the first surface of the substrate.

17. The device according to claim 16, wherein a solder ball is on the exposed through electrode.

18. The device according to claim 17, wherein the substrate is a substrate of an interposer and the solder ball provides electrical contact to a circuit board bonded to the interposer.

19. The device according to claim 11, wherein a top surface of the encapsulant and a top surface of the at least two semiconductor die are coplanar

20. A method for forming a semiconductor device, the method comprising:
bonding at least two semiconductor die to an interposer;
forming underfill material between the at least two semiconductor die and the interposer and between the at least two semiconductor die;
removing a portion of the underfill material between the at least two semiconductor die thereby forming a v-shaped groove; and
encapsulating the at least two semiconductor die, the underfill material, and the v-shaped groove using an encapsulant.
